(19) United States
(12) Patent Application Publication
(10) Pub. No.: US 2026/0075804 A1
(43) Pub. Date: Mar. 12, 2026

(54) SEMICONDUCTOR DEVICE AND SEMICONDUCTOR MEMORY DEVICE

(71) Applicant: Kioxia Corporation, Tokyo (JP)

(72) Inventors: Kasumi YASUDA, Yokohama Kanagawa (JP); Hiroki KAWAI, Inazawa Aichi (JP)

(21) Appl. No.: 19/064,594

(22) Filed: Feb. 26, 2025

(30) Foreign Application Priority Data
Sep. 12, 2024 (JP) 2024-158599

(51) Int. Cl. H10B 12/00

(52) U.S. Cl. CPC H10B 12/33

(57) ABSTRACT

A semiconductor device includes a channel including an oxide semiconductor and a first electrode in contact with the channel. The first electrode contains conductive oxide containing a first element that is an alkaline earth metal element and a second element that is a transition metal element.

### CROSS-REFERENCE TO RELATED APPLICATION

This application is based upon and claims the benefit of priority from Japanese Patent Application No. 2024-158599, filed Sep. 12, 2024, the entire contents of which are incorporated herein by reference.

### FIELD

Embodiments described herein relate generally to a semiconductor device and a semiconductor memory device.

### BACKGROUND

Known is a semiconductor device including a transistor element in which a channel formed of an oxide semiconductor (In—Ga—Zn—O: IGZO) is provided between a source and a drain formed of indium tin oxide (ITO). In recent years, as an oxide semiconductor-random access memory (RAM) is downsized, it is required to secure an on-current. To secure the on-current, it is necessary to reduce interface resistance between an electrode and a channel.

### BRIEF DESCRIPTION OF THE DRAWINGS

FIG. 1 is a cross-sectional view illustrating a cross section of a semiconductor device according to an embodiment.

FIG. 2 is a diagram illustrating characteristics required for an electrode material of the semiconductor device.

FIG. 3 is a diagram illustrating the characteristics required for the electrode material of the semiconductor device.

FIG. 4 is a diagram illustrating a perovskite-type crystal structure applicable to the electrode material of the semiconductor device.

FIG. 5 is a diagram illustrating a crystal structure applicable to the electrode material of the semiconductor device.

FIG. 6 is a diagram illustrating a crystal structure and a work function applicable to the electrode material of the semiconductor device.

FIG. 7 is a circuit diagram illustrating a circuit configuration example of a memory cell array.

FIG. 8 is a schematic cross-sectional view illustrating a structure example of the memory cell array.

FIG. 9 is a block diagram illustrating a configuration example of a semiconductor memory device.

### DETAILED DESCRIPTION

In a combination of an electrode formed of ITO and a channel formed of IGZO, a Schottky barrier may be formed at an interface between ITO and IGZO. Such structural configuration causes an increase in resistance between the electrode and a channel layer. Embodiments provide a semiconductor device and a semiconductor memory device capable of reducing interface resistance between an electrode and a channel.

In general, according to one embodiment, a semiconductor device comprises: a channel including an oxide semiconductor; and a first electrode in contact with the channel. The first electrode contains conductive oxide containing a first element that is an alkaline earth metal element and a second element that is a transition metal element.

### (Configuration)

Hereinafter, embodiments of this disclosure will be described with reference to the drawings. In the embodiments described below, the same components are denoted by the same reference numerals, and descriptions thereof may be partially omitted.

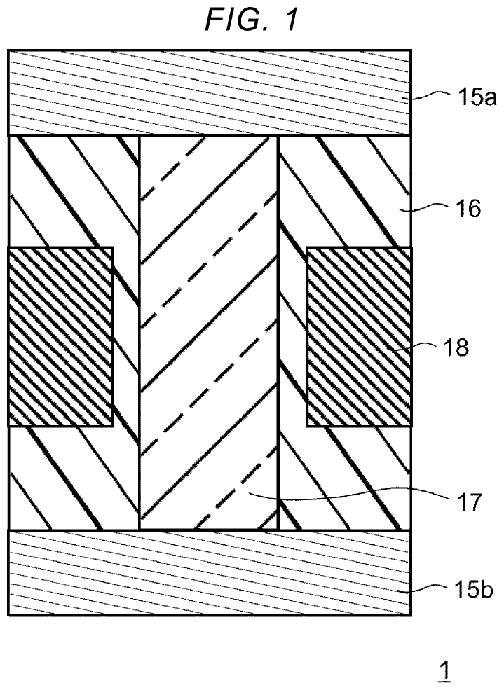

FIG. 1 is a cross-sectional view illustrating a basic configuration of a semiconductor device 1 according to an embodiment. The semiconductor device 1 is, for example, a semiconductor memory. The semiconductor device 1 illustrated in FIG. 1 includes a source electrode 15a, a drain electrode 15b, an insulating layer 16 disposed between the source electrode 15a and the drain electrode 15b, a channel 17 of which both ends are respectively joined to the source electrode 15a and the drain electrode 15b, and a gate electrode 18 disposed between the source electrode 15a and the drain electrode 15b and adjacent to the channel 17.

The source electrode 15a, the drain electrode 15b, and the gate electrode 18 are electrodes respectively corresponding to a source, a drain, and a gate of a transistor element of a semiconductor element. The source electrode 15a and the drain electrode 15b include conductive oxide. The gate electrode 18 includes, for example, a metal, a metal compound, or a semiconductor. The insulating layer 16 includes, for example, silicon dioxide (SiO2). The channel 17 includes an oxide semiconductor. An example of the oxide semiconductor of the channel 17 includes In—Ga—Zn—O (IGZO) containing indium, gallium, zinc, and oxygen. The source electrode 15a, the drain electrode 15b, the channel 17, and the gate electrode 18 form a memory transistor.

Here, an electrode material for the source electrode 15a and the drain electrode 15b will be described. Preferably, the electrode material does not form a Schottky barrier at a junction interface when the electrode material meets the channel 17 including the oxide semiconductor.

### (Work Function of Electrode)

When an electrode including ITO meets a channel including IGZO, a Schottky barrier may be formed, because a work function of the electrode and an electron affinity of the channel are very close in value. An effective magnitude relationship between the electrode and the channel is likely to be changed by factors such as atomic arrangement and composition of an interface, easily leading to formation of the Schottky barrier. The Schottky barrier formed at the junction interface has a function of increasing electrical resistance. To prevent formation of the Schottky barrier, an electrode material in which the work function is sufficiently lower than the electron affinity of IGZO (e.g., about 4.5 eV) in the channel 17 is selected as the electrode material.

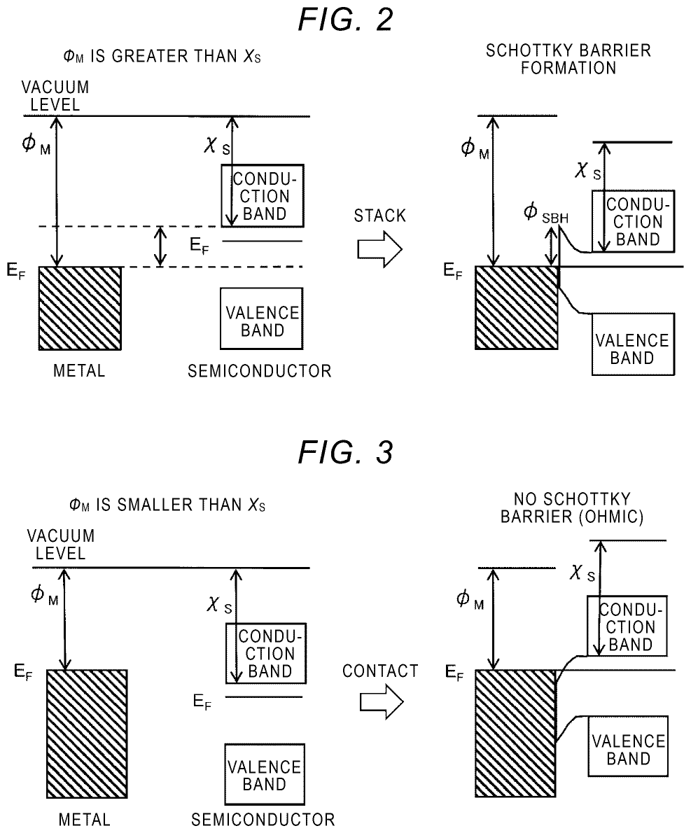

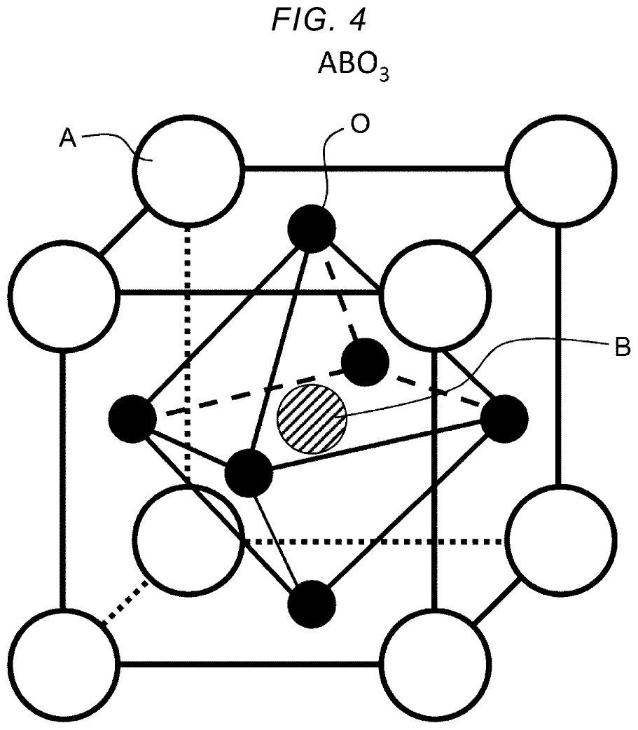

FIGS. 2 and 3 are diagrams each illustrating characteristics required for the electrode material in the semiconductor device 1.

As illustrated in FIG. 2, when a work function φM of an electrode is greater than an electron affinity XS of a semiconductor, a Schottky barrier is formed at an interface between the electrode and the semiconductor when the electrode and the semiconductor are stacked and brought into contact with each other. The Schottky barrier has a function of increasing resistance of the interface between the electrode and the semiconductor.

Meanwhile, as illustrated in FIG. 3, when the work function φM of the electrode is smaller than the electron affinity λ^{S} of the semiconductor, the interface becomes an ohmic junction when the electrode and the semiconductor contact each other, such that the Schottky barrier is not formed. Therefore, to reduce the electrical resistance at the interface between the electrode and the semiconductor, it is preferable to select an electrode material having a small work function φM.

### (Perovskite-Type Crystal)

In general, metal having a low work function has an unstable property. However, among oxides having a perovskite-type crystal structure, materials having a small work function and a stable property exist. FIG. 4 is a diagram illustrating an example of a perovskite-type crystal structure applicable to the electrode material in the semiconductor device 1.

The perovskite-type crystal structure is a structure in which three different types of atoms or ions are arranged in a specific positional relationship within a cubic lattice. FIG. 4 is a diagram illustrating an example of oxide ABO3, in which atoms A are disposed at corners of the cube, an atom B is disposed at a center of the cube, and oxygen atoms O are disposed at centers of planes of the cube. In the structure illustrated in FIG. 4, the atom A (or cation A) is slightly larger than the atom B (or cation B) and has coordination of 12, and the atom B has coordination of 6. A structure as such having a composition ratio of 1:1:3 is called an ABX3-type perovskite structure.

Perovskite-type oxide materials have a small work function and a metallic property when a specific cation such as strontium is placed at the position of the atom A. Therefore, by using perovskite-type oxide materials for the source electrode 15a and the drain electrode 15b, it is possible to obtain electrodes that do not generate a barrier at an interface. Since perovskite-type oxide is oxide, it is also possible to reduce influence of heat resistance (i.e., prevent oxygen from being extracted from IGZO).

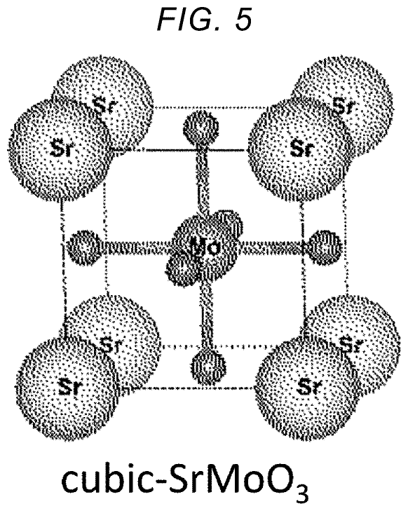

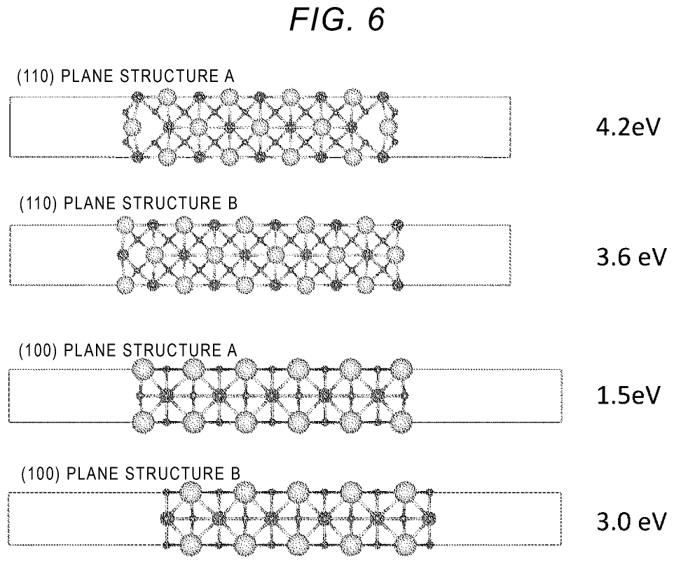

FIG. 5 is a diagram illustrating a crystal structure applicable to the electrode material of the semiconductor device 1. The structure illustrated in FIG. 5 is an example in which strontium is applied as the atom A and molybdenum is applied as the atom B (cubic-SrMoO3). FIG. 6 is a diagram illustrating a crystal structure and a work function applicable to the electrode material of the semiconductor device 1. FIG. 6 is a diagram illustrating a work function calculated regarding perovskite-type oxide having the structure illustrated in FIG. 5 based on density functional theory.

As illustrated in FIG. 6, in perovskite-type oxide having the structure illustrated in FIG. 5, the work function on a low index plane is 1.5 to 4.2 eV. The values are smaller than the electron affinity of IGZO (about 4.5 eV) in the channel 17 in any direction or plane, and formation of a barrier at an interface can be prevented. In other words, it can be said that perovskite-type oxide is suitable as the electrode material of the source electrode 15a and the drain electrode 15b.

### (Selection of Cation in Perovskite-Type Oxide)

A tolerance factor t is known as an index of stability and distortion of a crystal structure. The tolerance factor t is a dimensionless number calculated from a ratio of ionic radii and is acquired by the following Formula 1.

$$\begin{matrix}[ Formula 1 ] & \\ t = \frac{{r}_{A} + {r}_{O}}{\sqrt{2} ( {r}_{B} + {r}_{O} )} & ( 1 )\end{matrix}$$

Here, rA is a radius of a cation on an A site, rB is a radius of a cation on a B site, and rO is a radius of an oxygen anion. It is empirically known that the perovskite structure has a cubic structure when the tolerance factor t is approximately 0.9 to 1.0.

Therefore, the tolerance factor t is calculated using an alkaline earth metal as the atom A and a transition metal as the atom B. As a result, when magnesium, calcium, strontium, and barium are selected as the atom A, and vanadium, niobium, tantalum, chromium, molybdenum, tungsten, titanium, zirconium, and hafnium are selected as the atom B, the tolerance factor t became 0.76 to 1.084. Titanium, zirconium, and hafnium, that are Group 4 transition metals, are added or doped with vanadium, niobium, and tantalum, that are Group 5 transition metals, or chromium, molybdenum, and tungsten, that are Group 6 transition metals. That is, the combinations form a cubic perovskite structure, and are expected to form an ohmic junction when meeting a channel including IGZO.

As described above, it is preferable to select, as the electrode material in the semiconductor device 1, perovskite-type oxide of the general formula: ABO3, in which an alkaline earth metal is selected as the atom A, and a Group 5 or Group 6 transition metal or an n+ metal obtained by doping a Group 4 transition metal with a Group 5 or Group 6 transition metal element is selected as the atom B.

### (Semiconductor Device as Memory Device)

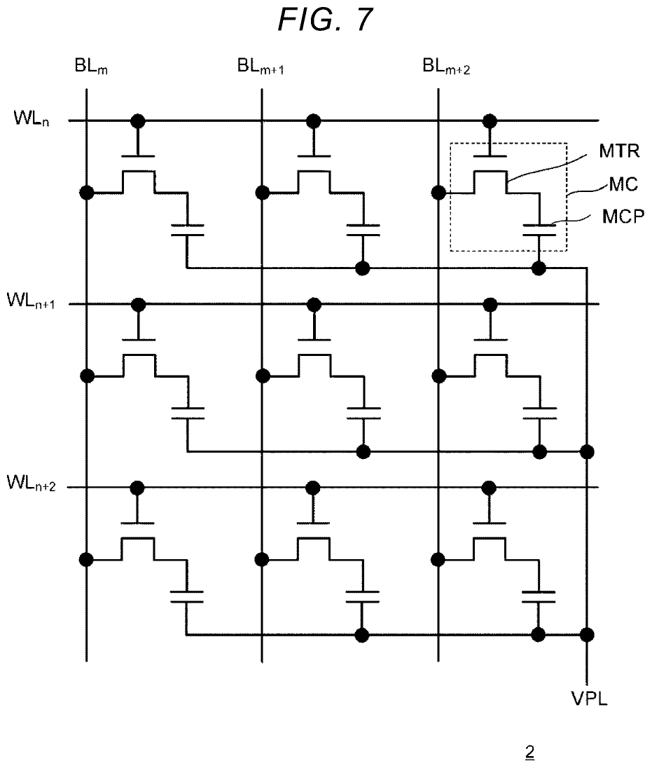

Next, a description will be given about a semiconductor memory device including the semiconductor device 1 with reference to FIGS. 1, 7, and 8. FIG. 7 is a circuit diagram illustrating a circuit configuration example of a memory cell array 2 as the semiconductor memory device. FIG. 7 illustrates a plurality of memory cells MC, a plurality of word lines WL (i.e., word line WLn, word line WLn+1, word line WLn+2, and n is an integer), a plurality of bit lines BL (i.e., bit line BLm, bit line BLm+1, bit line BLm+2, and m is an integer), and a power supply line VPL.

The memory cells MC are arranged in rows and columns to form the memory cell array 2. Each of the memory cells MC includes a memory transistor MTR, that is a field effect transistor (FET), and a memory capacitor MCP. The memory transistor MTR corresponds to the semiconductor device 1. The gate electrode 18 of the memory transistor MTR is connected to a corresponding word line WL, and one of the source electrode 15a and the drain electrode 15b is connected to a corresponding bit line BL. The word line WL is connected to, for example, a row decoder. The bit line BL is connected to, for example, a sense amplifier. A first electrode of the memory capacitor MCP is connected to the other of the source or the drain of the memory transistor MTR, and a second electrode of the memory capacitor MCP is connected to the power supply line VPL that supplies a specific voltage. The power supply line VPL is connected to, for example, a power supply circuit. The memory cell MC can store charges from the bit line BL in the memory capacitor MCP by switching of the memory transistor MTR by the word line WL, thereby storing data. The memory cell MC can read data based on the charges stored in the memory capacitor MCP to the bit line BL by switching of the memory transistor MTR by the word line WL. The number of memory cells MC is not limited to the number illustrated in FIG. 7.

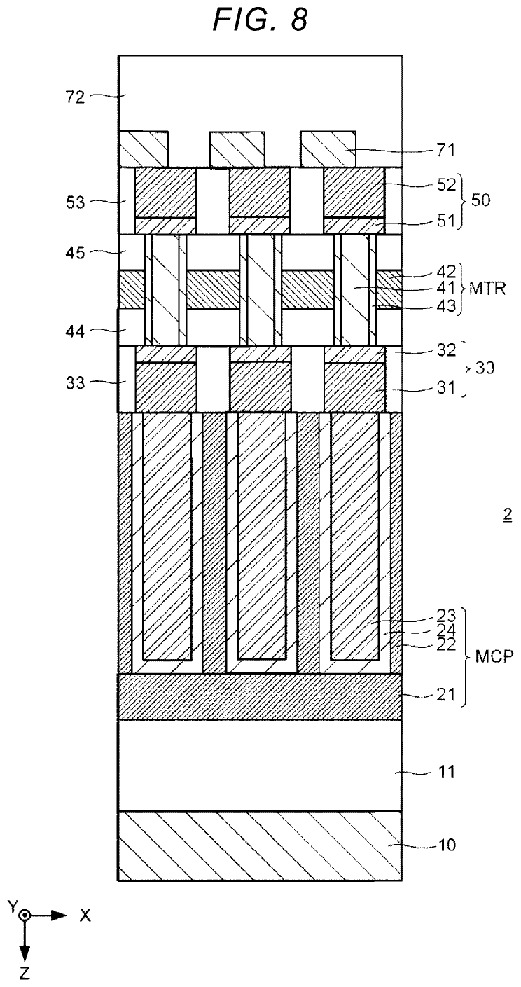

FIG. 8 is a schematic cross-sectional view illustrating a structural example of the memory cell array 2. FIG. 8 is a diagram illustrating a part of an X-Z cross section of an X-axis, a Y-axis, and a Z-axis that are orthogonal to each other. As illustrated in FIG. 8, the memory cell array 2 includes a conductor 21, a conductive layer 22, an electric conductor 23, an insulator 24, a conductive layer 31, a conductive oxide layer 32, an oxide semiconductor layer 41, a conductive layer 42, an insulating film 43, a conductive oxide layer 51, a conductive layer 52, and a conductive layer 71.

The memory transistor MTR and the memory capacitor MCP are provided above an insulating layer 11 on a semiconductor substrate 10, as illustrated in FIG. 8. On the semiconductor substrate 10, peripheral circuits such as the row decoder, the sense amplifier, and the power supply circuit are formed. The peripheral circuits include field effect transistors such as a P-channel field effect transistor (Pch-FET) and an N-channel field effect transistor (Nch-FET). The field effect transistors can be formed using the semiconductor substrate 10 such as a single crystal silicon substrate, and Pch-FET and Nch-FET include a channel region, a source region, and a drain region in the semiconductor substrate 10. The semiconductor substrate 10 may have a P-type conductivity. The insulating layer 11 is provided on the semiconductor substrate 10 and contains, for example, silicon (Si), and oxygen (O) or nitrogen (N). For example, the insulating layer 11 is a stacked film.

The conductor 21, the conductive layer 22, the electric conductor 23, and the insulator 24 form the memory capacitor MCP. The memory capacitor MCP is a three-dimensional capacitor such as a pillar-type capacitor or a cylinder-type capacitor.

The conductor 21 is provided above the semiconductor substrate 10 with the insulating layer 11 interposed therebetween. The conductive layer 22 is provided on a part of the conductor 21. The conductor 21 and the conductive layer 22 form the second electrode of the memory capacitor MCP. The conductor 21 extends to overlap a plurality of electric conductors 23 when viewed in a Z-axis direction. The conductor 21 is also referred to as a plate electrode. The electric conductor 23 is provided above the conductor 21 with the insulator 24 interposed therebetween, extends in the Z-axis direction, and configures the first electrode of the memory capacitor MCP. The insulator 24 is provided between the conductor 21 and the conductive layer 22, and the electric conductor 23, and forms a dielectric of the memory capacitor MCP.

The conductor 21 and the conductive layer 22 contain materials such as tungsten and titanium nitride. The electric conductor 23 contains materials such as tungsten, titanium nitride, and amorphous silicon. The insulator 24 contains materials such as hafnium oxide, zirconium oxide, and aluminum oxide.

The conductive layer 31 is provided on the electric conductor 23 and is electrically connected to the electric conductor 23. The conductive layer 31 contains, for example, copper. Note that it is not essential to form the conductive layer 31.

The conductive oxide layer 32 is provided on the conductive layer 31. For example, the conductive oxide layer 32 contains conductive oxide.

The conductive layer 31 and the conductive oxide layer 32 form a conductor 30. A plurality of conductors 30 are provided corresponding to the plurality of electric conductors 23. An insulating layer 33 is formed between the plurality of conductors 30. The insulating layer 33 contains, for example, silicon, and oxygen or nitrogen.

The oxide semiconductor layer 41, the conductive layer 42, and the insulating film 43 form the memory transistor MTR. The memory transistor MTR is, for example, an N-channel field effect transistor. The memory transistor MTR is provided above the memory capacitor MCP. A plurality of memory transistors MTR are provided corresponding to the plurality of memory capacitors MCP. An insulating layer 44 and an insulating layer 45 are formed between the plurality of memory transistors MTR. The insulating layer 44 and the insulating layer 45 contain, for example, silicon, and oxygen or nitrogen.

The oxide semiconductor layer 41 is, for example, a columnar body extending in the Z-axis direction. The oxide semiconductor layer 41 penetrates the conductive layer 42 in the Z-axis direction. The oxide semiconductor layer 41 forms the channel of the memory transistor MTR (i.e., the channel 17 in the semiconductor device 1). The oxide semiconductor layer 41 contains, for example, indium (In). The oxide semiconductor layer 41 contains, for example, indium oxide and gallium oxide, indium oxide and zinc oxide, or indium oxide and tin oxide. As an example, the oxide semiconductor layer 41 contains oxide containing indium, gallium, and zinc (indium-gallium-zinc-oxide), so-called IGZO (InGaZnO).

One end of the oxide semiconductor layer 41 in the Z-axis direction is connected to the conductive layer 31 with the conductive oxide layer 32 interposed therebetween, and functions as the other of the source electrode 15a or the drain electrode 15b of the memory transistor MTR. The conductive oxide layer 32 is provided between the electric conductor 23 of the memory capacitor MCP and the oxide semiconductor layer 41 of the memory transistor MTR, and functions as the other of the source electrode 15a or the drain electrode 15b of the memory transistor MTR.

Similarly to the semiconductor device 1, the conductive oxide layer 32 in which the work function φM is smaller than the electron affinity λS of the oxide semiconductor layer 41 can be selected. That is, it is possible to select, as a material of the conductive oxide layer 32, perovskite-type oxide of the general formula: ABO3, in which an alkaline earth metal is selected as the atom A, and a Group 5 or Group 6 transition metal or an n+ metal obtained by doping a Group 4 transition metal with a Group 5 or Group 6 transition metal element is selected as the atom B. Accordingly, it is possible to reduce connection resistance between the memory transistor MTR and the memory capacitor MCP.

The conductive layer 42 includes a portion facing the oxide semiconductor layer 41 with the insulating film 43 interposed therebetween on the X-Y plane. The conductive layer 42 forms the gate electrode 18 of the memory transistor MTR and also forms the word line WL as wiring. The conductive layer 42 includes, for example, metal, a metal compound, or a semiconductor. The conductive layer 42 includes, for example, at least one material selected from the group consisting of tungsten (W), titanium (Ti), titanium nitride (TiN), molybdenum (Mo), cobalt (Co), and ruthenium (Ru).

The plurality of conductive layers 42 extend in an X-axis direction and are arranged parallel with each other. Each conductive layer 42 overlaps the plurality of memory cells MC and are connected thereto in the X-axis direction.

The insulating film 43 is provided between the oxide semiconductor layer 41 and the conductive layer 42 on the X-Y plane. The insulating film 43 forms a gate insulating film of the memory transistor MTR. The insulating film 43 contains, for example, silicon, and oxygen or nitrogen. The insulating film 43 may be a stacked film of the plurality of insulating films.

The memory transistor MTR is a so-called surrounding gate transistor (SGT) in which the gate electrode 18 is disposed to surround the channel 17. An area of the semiconductor device can be reduced by SGT.

A field effect transistor including a channel layer containing an oxide semiconductor has a lower off-leak current than a field effect transistor provided on the semiconductor substrate 10. Therefore, for example, data stored in the memory cell MC can be stored for a long period of time, and the number of refresh operations can be reduced. The field effect transistor including the channel layer containing the oxide semiconductor can be formed by a low-temperature process, thereby reducing thermal stress on the memory capacitor MCP.

The conductive oxide layer 51 is provided on the oxide semiconductor layer 41. For example, the conductive oxide layer 51 includes conductive oxide.

The conductive layer 52 is provided on the conductive oxide layer 51 and is electrically connected to the conductive oxide layer 51. The conductive layer 52 contains, for example, copper.

The conductive oxide layer 51 and the conductive layer 52 form a conductor 50. The conductor 50 is electrically connected to the sense amplifier via the bit line BL. The conductor 50 functions as, for example, a conductive pad for connecting the memory transistor MTR to the bit line BL. A plurality of conductors 50 are provided corresponding to the plurality of memory transistors MTR. An insulating layer 53 is formed between the plurality of conductors 50. The insulating layer 53 contains, for example, silicon, and oxygen or nitrogen.

The other end of the oxide semiconductor layer 41 in the Z-axis direction is connected to the conductive layer 52 with the conductive oxide layer 51 interposed therebetween, and functions as one of the source and the drain of the memory transistor MTR. The conductive oxide layer 51 functions as one of the source electrode 15a and the drain electrode 15b of the memory transistor MTR.

The conductive oxide layer 51 in which the work function φM thereof is smaller than the electron affinity λS of the oxide semiconductor layer 41 can be selected. That is, as a material of the conductive oxide layer 51, it is possible to select perovskite-type oxide of the general formula: ABO3, in which an alkaline earth metal is selected as the atom A, and a Group 5 or Group 6 transition metal or an n+ metal obtained by doping a Group 4 transition metal with a Group 5 or Group 6 transition metal element is selected as the atom B. Accordingly, it is possible to reduce connection resistance between the memory transistor MTR and the memory capacitor MCP.

The conductive layer 71 is provided on the conductive layer 52 and is connected to the conductor 50. The conductive layer 71 forms the bit line BL as wiring. An insulating layer 72 is formed between the plurality of conductive layers 71. The insulating layer 72 contains, for example, silicon, and oxygen or nitrogen.

The plurality of memory cells MC may be arranged in a staggered arrangement on the X-Y plane. The memory cell MC connected to one of the plurality of word lines WL is disposed to be shifted in the X-axis direction relative to the memory cell MC connected to an adjacent word line WL. Accordingly, a degree of integration of the memory cells MC can be increased.

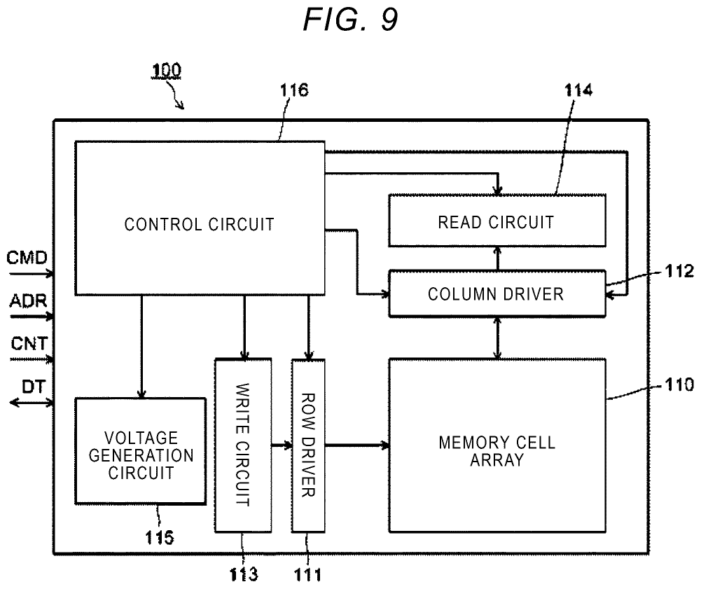

FIG. 9 is a block diagram illustrating a configuration example of the semiconductor memory device. A storage device 100 includes a memory cell array 110, a row driver 111, a column driver 112, a write circuit 113, a read circuit 114, a voltage generation circuit 115, and a control circuit 116. The memory cell array 110 includes the semiconductor memory device described above.

The row driver 111 controls a plurality of rows of memory cells in the memory cell array 110. The row driver 111 receives, from the control circuit 116, a row address signal based on a decoded result of an address signal ADR input from the outside. The row driver 111 sets the word line WL of a row selected by the row address signal to a selected state. The row driver 111 includes circuits such as a multiplexer and a word line driver.

The column driver 112 controls a plurality of columns of memory cells in the memory cell array 110. The column driver 112 receives, from the control circuit 116, a column address signal based on the decoded result of the address signal ADR. The column driver 112 sets the bit line BL of a column selected by the column address signal to a selected state. The column driver 112 includes circuits such as a multiplexer and a bit line driver.

The write circuit 113 performs various types of control for a data write operation. The write circuit 113 receives a data signal DT input from the outside. During the write operation, the write circuit 113 supplies a write pulse formed by current and/or voltage to the memory cell array 110. Accordingly, data can be written to the memory cells MC. The write circuit 113 is electrically connected to the memory cell array 110 via the row driver 111. The write circuit 113 includes circuits such as a voltage source and/or a current source, a pulse generating circuit, and a latch circuit.

The read circuit 114 performs various types of control for a data read operation. During the read operation, the read circuit 114 supplies a read pulse (for example, read voltage) to the memory cell array 110. The read circuit 114 performs sensing of a voltage or current value of the bit line BL. Based on the sensing result, data in the memory cell MC can be read. The read circuit 114 transfers the read data signal to the outside. The read circuit 114 is connected to the memory cell array 110 via the column driver 112. The read circuit 114 includes circuits such as a voltage source and/or a current source, a pulse generation circuit, a latch circuit, and a sense amplifier circuit.

The write circuit 113 and the read circuit 114 are not limited to circuits independent of each other. For example, the write circuit 113 and the read circuit 114 may include common components capable of being mutually used and may be disposed in the storage device 100 as a single integrated circuit.

The voltage generation circuit 115 generates voltages for various types of operation of the memory cell array 110 using a power supply voltage supplied from the outside. The voltage generation circuit 115 supplies the generated various voltages to the row driver 111, the column driver 112, the write circuit 113, and the read circuit 114, respectively.

The control circuit 116 includes, for example, a command register and an address register. The control circuit 116 controls the row driver 111, the column driver 112, the write circuit 113, the read circuit 114, and the voltage generation circuit 115 based on a command signal CMD, the address signal ADR, and a control signal CNT input from the outside, thereby performing operations such as a read operation, a write operation, and an erasing operation.

The command signal CMD is a signal indicating an operation to be performed by the storage device 100. For example, the address signal ADR is a signal indicating coordinates of one or more memory cells MC to be operated (referred to as selected cells) in the memory cell array 110. The address signal ADR includes the row address signal and the column address signal of the memory cell MC. The control signal CNT is a signal for controlling, for example, a timing of operation between the storage device 100 and an external device and a timing of operation in the storage device 100.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a channel including an oxide semiconductor; and
a first electrode in contact with the channel, wherein
the first electrode contains conductive oxide containing a first element that is an alkaline earth metal element and a second element that is a transition metal element.

2. The semiconductor device according to claim 1, wherein
a composition ratio of the first element, the second element, and oxygen in the conductive oxide is 1:1:3.

3. The semiconductor device according to claim 1, wherein
the conductive oxide has a perovskite-type crystal structure.

4. The semiconductor device according to claim 1, wherein
the conductive oxide has a composition represented by a general formula: ABO3, in which A is the first element and B is the second element.

5. The semiconductor device according to claim 1, wherein
the second element is at least one element selected from the group of Group 4, Group 5, and Group 6 transition metal elements.

6. The semiconductor device according to claim 1, wherein
the first element is at least one alkaline earth metal element selected from the group consisting of magnesium, calcium, strontium, and barium.

7. The semiconductor device according to claim 6, wherein
the second element is at least one transition metal element selected from the group consisting of vanadium, niobium, tantalum, chromium, molybdenum, tungsten, titanium, zirconium, and hafnium.

8. The semiconductor device according to claim 7, wherein
the second element includes at least one transition metal element selected from the group consisting of titanium, zirconium, and hafnium, and at least one transition metal element selected from the group consisting of vanadium, niobium, tantalum, chromium, molybdenum, and tungsten.

9. The semiconductor device according to claim 1, further comprising:
a second electrode in contact with the channel and containing the conductive oxide.

10. The semiconductor device according to claim 9, further comprising:
a third electrode between the first and second electrodes and insulated from the first and second electrodes and the channel.

11. A semiconductor memory device comprising:
a channel including an oxide semiconductor;
a first electrode in contact with the channel; and
a capacitor electrically connected to the first electrode, wherein
the first electrode contains conductive oxide containing a first element that is an alkaline earth metal element and a second element that is a transition metal element.

12. The semiconductor memory device according to claim 11, wherein
a composition ratio of the first element, the second element, and oxygen in the conductive oxide is 1:1:3.

13. The semiconductor memory device according to claim 11, wherein
the conductive oxide has a perovskite-type crystal structure.

14. The semiconductor memory device according to claim 11, wherein
the conductive oxide has a composition represented by a general formula: ABO3, in which A is the first element and B is the second element.

15. The semiconductor memory device according to claim 11, wherein
the second element is at least one element selected from the group of Group 4, Group 5, and Group 6 transition metal elements.

16. The semiconductor memory device according to claim 11, wherein
the first element is at least one alkaline earth metal element selected from the group consisting of magnesium, calcium, strontium, and barium.

17. The semiconductor memory device according to claim 16, wherein
the second element is at least one transition metal element selected from the group consisting of vanadium, niobium, tantalum, chromium, molybdenum, tungsten, titanium, zirconium, and hafnium.

18. The semiconductor memory device according to claim 17, wherein
the second element includes at least one transition metal element selected from the group consisting of titanium, zirconium, and hafnium, and at least one transition metal element selected from the group consisting of vanadium, niobium, tantalum, chromium, molybdenum, and tungsten.

19. The semiconductor memory device according to claim 11, further comprising:
a second electrode in contact with the channel and containing the conductive oxide; and
a third electrode between the first and second electrodes and insulated from the first and second electrodes and the channel.

20. A semiconductor memory device comprising:
a memory cell array;
a driver configured to apply a voltage to the memory cell array; and
a control circuit configured to control the driver, wherein
the memory cell array includes:
a channel including an oxide semiconductor,
a first electrode in contact with the channel, and
a capacitor electrically connected to the first electrode, and
the first electrode contains conductive oxide containing a first element that is an alkaline earth metal element and a second element that is a transition metal element.
